(19) United States
(12) Patent Application Publication
(10) Pub. No.: US 2026/0248042 A1
(43) Pub. Date: Aug. 20, 2026

(54) ELECTRONIC PACKAGE

(71) Applicant: SILICONWARE PRECISION INDUSTRIES CO., LTD., Taichung City (TW)

(72) Inventors: Chih-Wen CHEN, Taichung City (TW); Sung-Hua CHUNG, Taichung City (TW)

(73) Assignee: SILICONWARE PRECISION INDUSTRIES CO., LTD., Taichung City (TW)

(21) Appl. No.: 19/311,804

(22) Filed: Aug. 27, 2025

(30) Foreign Application Priority Data
Feb. 17, 2025 (TW) 114105753

(51) Int. Cl. H01L 25/16; H01L 23/00

(52) U.S. Cl. CPC H10W 90/00; H10W 72/242; H10W 72/248; H10W 72/252; H10W 90/722

(57) ABSTRACT

An electronic package includes a substrate, an electronic component stacked on the substrate, and an optoelectronic module stacked on the electronic component. The electronic component is formed with a plurality of conductive vias, so that the optoelectronic module can be electrically connected to the electronic component and the substrate via the plurality of conductive vias, thereby shortening the path of electrical transmission.

### BACKGROUND

### 1. Technical Field

The present disclosure relates to a semiconductor structure, and more particularly, to an electronic package having an optoelectronic module.

### 2. Description of Related Art

With the vigorous development of the electronics industry, electronic products are gradually progressing towards multi-functionality and high performance. The current fifth generation (5G) communication technology has been applied to various fields such as Internet of Things (IoT), Industrial Internet of Things (IIoT), cloud, artificial intelligence (AI), autonomous cars, and medical care. With the expansion of the application level, a large amount of data is generated that needs to be efficiently transmitted, computed and stored. In particular, there is a huge demand for data transmission. Therefore, the industry has begun to use “light” instead of “electricity” as the carrier of data transmission to increase the transmission capacity, efficiency, or distance, and reduce energy consumption during the transmission process. In this context, co-packaged optics has become the development trend of future semiconductor and packaging technology.

Please refer to FIG. 1A and FIG. 1B, which are a schematic cross-sectional view and a schematic partial top view of a conventional optical device 1 of co-packaged optics. The optical device 1 mainly has an optoelectronic module 11 disposed on a circuit board 10. The optoelectronic module 11 includes a semiconductor chip 112 formed in a package structure 111 and an optical chip 113 connected to the package structure 111, so that optical signals are transmitted to the optoelectronic module 11 for communication. At the same time, the circuit board 10 needs to be equipped with a switch chip 12 (e.g., a switch integrated circuit) before the optical device 1 can be used in a terminal product, wherein the switch chip 12 is firstly disposed on a substrate 13 and then is connected to the circuit board 10 via the substrate 13.

However, the optical chip 113 and the switch chip 12 in the optical device 1 of co-packaged optics need to establish connections for electrical communication via circuits inside the circuit board 10 and the substrate 13. However, the paths of the circuits are too long, resulting in slow signal transmission and loss, thereby causing problems of applications in the terminal product.

Therefore, how to overcome the above-mentioned drawbacks of the prior art has become an urgent issue to be solved.

### SUMMARY

In view of the various deficiencies of the prior art, the present disclosure provides an electronic package, which comprises: a substrate having a first side and a second side opposite to the first side; an electronic component having a first surface and a second surface opposite to the first surface, wherein the second surface of the electronic component is connected to the first side of the substrate, and the electronic component is formed with a plurality of conductive vias penetrating through the first surface and the second surface; and an optoelectronic module connected to the first surface of the electronic component and electrically connected to the plurality of conductive vias.

In the aforementioned electronic package, the electronic component is a switch application-specific integrated circuit.

In the aforementioned electronic package, the second surface of the electronic component is electrically connected to the substrate via a plurality of conductive bumps.

In the aforementioned electronic package, the optoelectronic module includes a package structure, a semiconductor component disposed in the package structure, and an optical component connected to the package structure. In one embodiment, the semiconductor component is an electronic integrated circuit component. In one embodiment, the optical component is an optical chip or an optical module. In one embodiment, the optical module includes a coupler, an optical chip, a total reflection mirror and an optical fiber array unit.

In the aforementioned electronic package, the optoelectronic module is connected to the first surface of the electronic component via conductive elements disposed on the package structure, and the optoelectronic module is electrically connected to the electronic component.

In the aforementioned electronic package, the present disclosure further comprises a plurality of conductive components placed on the second side of the substrate.

In the aforementioned electronic package, the substrate, the electronic component and the optoelectronic module form a three-layer vertical stacking structure.

As can be seen from the above, in the electronic package of the present disclosure, a plurality of conductive vias are formed in an electronic component, and the electronic component is disposed on a substrate. Further, an optoelectronic module including an optical component and a semiconductor component is directly connected to the electronic component, so that the optoelectronic module can be electrically connected to the electronic component and the substrate via the plurality of conductive vias, thereby shortening the path of electrical transmission and reducing the loss of data transmission.

### BRIEF DESCRIPTION OF THE DRAWINGS

FIG. 1A and FIG. 1B are a schematic cross-sectional view and a schematic partial top view of a conventional optical device of co-packaged optics.

FIG. 2A and FIG. 2B are a schematic cross-sectional view and a schematic partial top view of an electronic package according to the present disclosure.

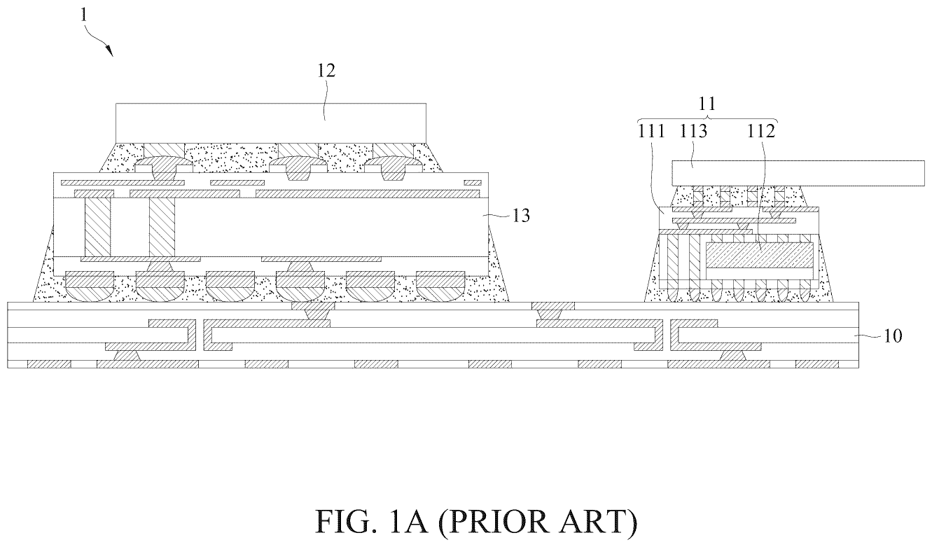

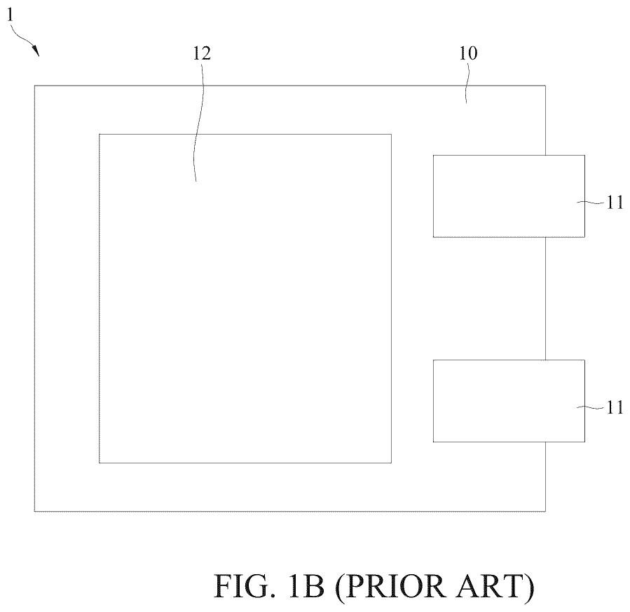

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “third,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

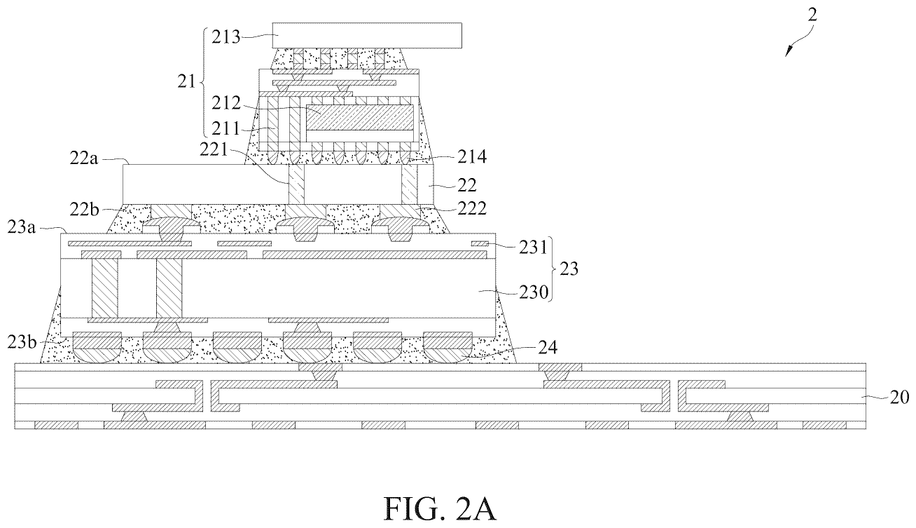

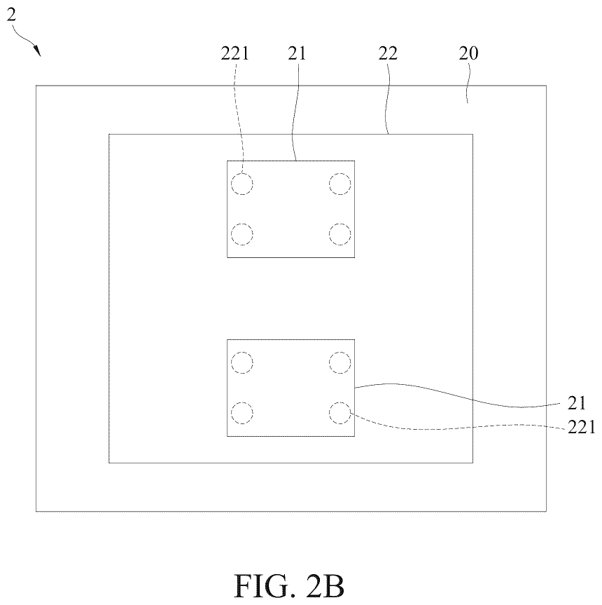

Please refer to FIG. 2A and FIG. 2B, which are a schematic cross-sectional view and a schematic partial top view of an electronic package 2 according to the present disclosure.

The electronic package 2 includes a substrate 23, an electronic component 22 disposed on the substrate 23, and an optoelectronic module 21 disposed on the electronic component 22.

The substrate 23 is, for example, a core substrate with a core layer or a coreless substrate without a core layer. The substrate 23 has a first side 23a and a second side 23b opposite to the first side 23a.

In one embodiment, the substrate 23 includes at least one insulating layer 230 and at least one circuit layer 231 bonded to the insulating layer 230. The insulating layer 230 is made of, for example, dielectric material such as polybenzoxazole (PBO), polyimide (PI), prepreg (PP), or the like. The circuit layer 231 is, for example, a fan-out redistribution layer, and the circuit layer 231 is made of, for example, copper metal.

The electronic component 22 is disposed on the first side 23a of the substrate 23 and is electrically connected to the substrate 23.

The electronic component 22 is, for example, a switch application-specific integrated circuit (switch ASIC), and the electronic component 22 has a first surface 22a and a second surface 22b opposite to the first surface 22a. A plurality of conductive vias 221 (e.g., conductive through-silicon vias) penetrating through the first surface 22a and the second surface 22b are formed in the electronic component 22, so that the second surface 22b of the electronic component 22 is electrically connected to the circuit layer 231 of the substrate 23 via a plurality of conductive bumps 222 (e.g., solder bumps or copper bumps).

The optoelectronic module 21 is disposed on the first surface 22a of the electronic component 22 and is electrically connected to the plurality of conductive vias 221 of the electronic component 22.

The optoelectronic module 21 includes a package structure 211, a semiconductor component 212 disposed in the package structure 211, and an optical component 213 connected to the package structure 211. The package structure 211 is, for example, a fan-out package-on-package (FO-PoP) structure. The semiconductor component 212 is, for example, an electronic integrated circuit component (electronic IC [EIC]). The optical component 213 is, for example, an optical chip or an optical module (photonic integrated circuit [PIC] module), wherein the optical module includes a coupler, an optical chip, a total reflection mirror, an optical fiber array unit (FAU), etc.

The optoelectronic module 21 can be connected to the first surface 22a of the electronic component 22 via conductive elements 214 (such as solder bumps or copper bumps) disposed on the package structure 211, and the optoelectronic module 21 can be electrically connected to the electronic component 22. As shown in FIG. 2B, the plurality of conductive vias 221 of the electronic component 22 are located within a vertical projection area of the optoelectronic module 21, so that the optoelectronic module 21 can directly utilize the conductive vias 221 of the electronic component 22 to electrically connect the electronic component 22, the substrate 23, or other components, so as to shorten the electrical transmission path and reduce data transmission loss.

In addition, a plurality of conductive components 24 (such as solder bumps or copper bumps) can be placed on the second side 23b of the substrate 23, so that the substrate 23 can be electrically connected to a circuit board 20 via the plurality of conductive components 24 later.

Accordingly, in the electronic package of the present disclosure, an electronic component having a plurality of conductive vias is vertically stacked on a substrate, and an optoelectronic module including an EIC/PIC is vertically stacked on the electronic component to form an electronic package of a three-layer vertical stacking structure. Therefore, the present disclosure accelerates an electrical communication among the substrate, the electronic component and the optoelectronic module via the vertical electrical connection.

In summary, in the electronic package of the present disclosure, a plurality of conductive vias are formed in an electronic component, and the electronic component is disposed on a substrate. Further, an optoelectronic module including an optical component and a semiconductor component is directly connected to the electronic component, so that the optoelectronic module can be electrically connected to the electronic component and the substrate via the plurality of conductive vias, thereby shortening the path of electrical transmission and reducing the loss of data transmission. In addition, the electronic package has high technical feasibility and can be manufactured using existing semiconductor packaging processes without the need to develop special processes or purchase special equipment, thereby reducing product manufacturing costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a substrate having a first side and a second side opposite to the first side;
an electronic component having a first surface and a second surface opposite to the first surface, wherein the second surface of the electronic component is connected to the first side of the substrate, and the electronic component is formed with a plurality of conductive vias penetrating through the first surface and the second surface; and
an optoelectronic module connected to the first surface of the electronic component and electrically connected to the plurality of conductive vias.

2. The electronic package of claim 1, wherein the electronic component is a switch application-specific integrated circuit.

3. The electronic package of claim 1, wherein the second surface of the electronic component is electrically connected to the substrate via a plurality of conductive bumps.

4. The electronic package of claim 1, wherein the optoelectronic module includes a package structure, a semiconductor component disposed in the package structure, and an optical component connected to the package structure.

5. The electronic package of claim 4, wherein the semiconductor component is an electronic integrated circuit component.

6. The electronic package of claim 4, wherein the optical component is an optical chip or an optical module.

7. The electronic package of claim 6, wherein the optical module includes a coupler, an optical chip, a total reflection mirror and an optical fiber array unit.

8. The electronic package of claim 4, wherein the optoelectronic module is connected to the first surface of the electronic component via conductive elements disposed on the package structure, and the optoelectronic module is electrically connected to the electronic component.

9. The electronic package of claim 1, further comprising a plurality of conductive components placed on the second side of the substrate.

10. The electronic package of claim 1, wherein the substrate, the electronic component and the optoelectronic module form a three-layer vertical stacking structure.
